(19) United States
(12) Patent Application Publication
(10) Pub. No.: US 2026/0266742 A1
(43) Pub. Date: Sep. 10, 2026

(54) TERAHERTZ SYSTEM AND CONTROL DEVICE

(71) Applicant: ROHM CO., LTD., Kyoto (JP)

(72) Inventor: Koji TERUMOTO, Kyoto-shi (JP)

(73) Assignee: ROHM CO., LTD., Kyoto (JP)

(21) Appl. No.: 19/659,131

(22) Filed: Apr. 27, 2026

Related U.S. Application Data
(63) Continuation of application No. PCT/JP2024/037591, filed on Oct. 22, 2024.

(30) Foreign Application Priority Data
Oct. 31, 2023 (JP) 2023-187096

(51) Int. Cl. G01N 22/00

(52) U.S. Cl. CPC G01N 22/00

(57) ABSTRACT

This terahertz system includes: a transmitter that includes a first active element which oscillates a terahertz wave on the basis of the application of a first drive voltage, the transmitter being configured to be capable of transmitting the terahertz wave; a receiver that includes a second active element capable of detecting the terahertz wave on the basis of the application of a second drive voltage, and is configured to be able to receive the terahertz wave; and a control circuitry that outputs the first drive voltage and the second drive voltage. The control circuitry periodically and continuously changes the first drive voltage and the second drive voltage.

### CROSS-REFERENCE TO RELATED APPLICATIONS

This application is a continuation of, and claims the benefit of priority from International Application No. PCT/JP2024/ 037591, filed on October 22, 2024, which claims the benefit of priority from Japanese Patent Application No. 2023-187096, filed on October 31, 2023, the entire contents of each of which are incorporated herein by reference.

### BACKGROUND

### 1. Field

The present disclosure relates to a terahertz system and a control device.

### 2. Description of Related Art

The trend toward miniaturization of electronic devices such as transistors has led to nano-scale devices that exhibit quantum effects. Devices that utilize quantum effects and operate at an ultra-high speed or have a novel function are currently under development.

In such an environment, there is ongoing research aimed at utilizing electromagnetic waves in the frequency range referred to as the terahertz band, which covers frequencies from 0.1 THz to 10 THz, for large-capacity communication, information processing, imaging, and measurement (refer to, for example, JP2020-115500A). This frequency range exhibits characteristics of both light and radio waves. Therefore, if devices capable of operating in this frequency range can be developed, the devices are applicable to a wide variety of fields, including physical property measurement, astronomy, and biology, as well as imaging, large-capacity communication, and information processing.

### BRIEF DESCRIPTION OF DRAWINGS

FIG. 1 is a schematic diagram showing a transmission-type terahertz system.

FIG. 2 is a schematic block diagram showing the electrical configuration of the terahertz system.

FIG. 3 is a circuit diagram of a transmitter.

FIG. 4 is a circuit diagram of a receiver, an extraction circuit, and an amplification circuit.

FIG. 5 is a diagram showing the relationship between the receiving sensitivity of a second active element and a second drive voltage.

FIG. 6 is a waveform chart of a first drive voltage having a ramp-up waveform.

FIG. 7 is a waveform chart of a first drive voltage having a ramp-down waveform.

FIG. 8 is a waveform chart of a first drive voltage having a triangle waveform.

FIG. 9 is a waveform chart of a first drive voltage having a sine waveform.

FIG. 10 is a waveform chart of a second drive voltage having a ramp-up waveform.

FIG. 11 is a waveform chart of a second drive voltage having a ramp-down waveform.

FIG. 12 is a waveform chart of a second drive voltage having a triangle waveform.

FIG. 13 is a waveform chart of a second drive voltage having a sine waveform.

FIG. 14 is a flowchart of received signal processing in the first embodiment.

FIG. 15 is a diagram showing the relationship between the second drive voltage and a signal strength error.

FIG. 16 is a flowchart of received signal processing in a second embodiment.

FIG. 17 is a schematic diagram showing a reflection-type terahertz system.

### DETAILED DESCRIPTION

Several embodiments of a terahertz system, a control device, a method for controlling a terahertz system and a method for controlling a control device in accordance with the present disclosure will now be described with reference to the accompanying drawings. The accompanying drawings illustrate exemplary embodiments in accordance with the present disclosure and are not intended to limit the present disclosure.

This detailed description includes exemplary embodiments of apparatuses, systems, and methods in accordance with the present disclosure. This detailed description is illustrative and is not intended to limit embodiments of the present disclosure or the application and use of the embodiments.

### First Embodiment

A terahertz system 10 and a control device 40 in accordance with the present embodiment will now be described. The terahertz system 10 in accordance with the present embodiment is used to perform an inspection, such as non-destructive imaging or chemical composition analysis, on a detection target 50. The detection target 50 is generally a solid. This, however, is not a limitation, and the detection target 50 may be a liquid or a gas.

### Outline of the Terahertz System

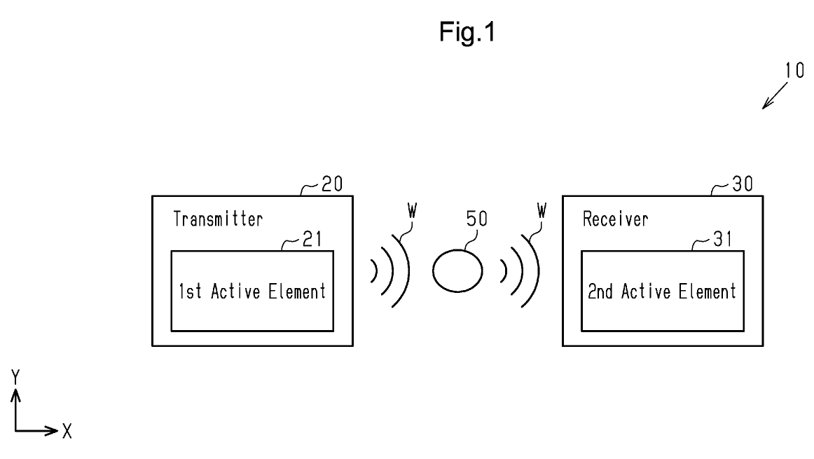

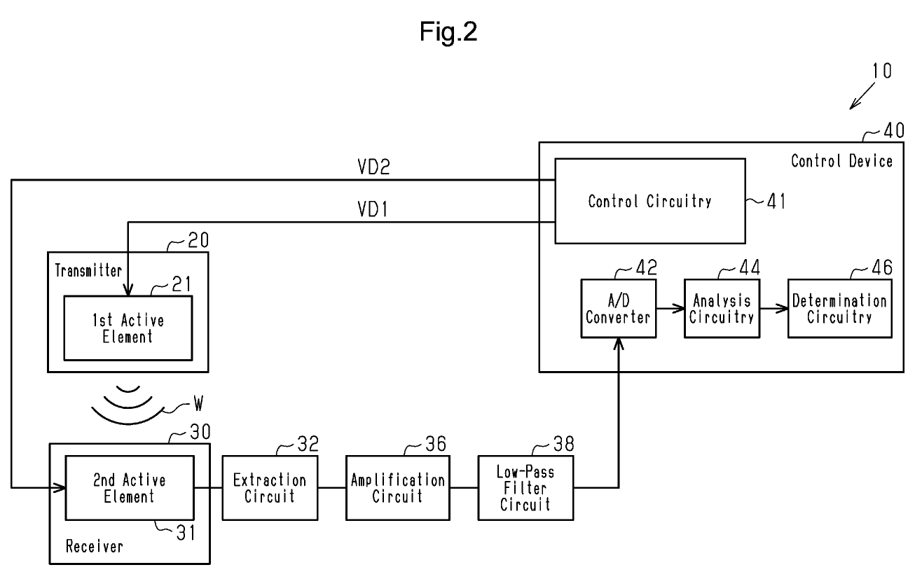

As shown in FIGS. 1 and 2, the terahertz system 10 includes a transmitter 20, for transmitting terahertz waves W, and a receiver 30, for detecting terahertz waves W. The terahertz waves W are electromagnetic waves in the frequency range of 0.1 THz to 10 THz.

As shown in FIG. 1, in the present embodiment, the transmitter 20 and the receiver 30 are arranged at opposite sides of the detection target 50 in a first direction X. The transmitter 20 transmits the terahertz waves W toward, for example, the detection target 50. The receiver 30 is positioned to receive the terahertz waves W that are transmitted from the transmitter 20 and pass through the detection target 50. The terahertz waves W received by the receiver 30 may attenuate when passing through the detection target 50. In this specification, unless otherwise specified, the terahertz waves W include both the terahertz waves W transmitted from the transmitter 20 and the terahertz waves W received by the receiver 30.

The transmitter 20 includes a first active element 21 that performs conversion between electric energy and terahertz waves W. The first active element 21 oscillates when a first drive voltage VD1 is applied. As a result, the transmitter 20 transmits the terahertz waves W. The transmitter 20 may include an antenna to direct the terahertz waves W generated by the first active element 21 in the first direction X.

The receiver 30 includes a second active element 31 that performs conversion between electric energy and terahertz waves W. The second active element 31 is configured to detect the terahertz waves W when a second drive voltage VD2 is applied. More specifically, the second active element 31 converts the terahertz waves W into voltage (i.e., analog signal), which is electric energy.

The first active element 21 and the second active element 31 are typically resonant tunneling diodes (RTDs). Instead, the first active element 21 and the second active element 31 may each be, for example, a tunnel injection transit time (TUNNETT) diode, an impact ionization avalanche transit time (IMPATT) diode, a GaAs field effect transistor (FET), a GaN FET, a high electron mobility transistor (HEMT), or a heterojunction bipolar transistor (HBT). The two active elements 21 and 31 are semiconductor oscillation elements that operate in the terahertz band.

As shown in FIG. 2, the terahertz system 10 includes an extraction circuit 32, an amplification circuit 36, a low-pass filter circuit 38, and the control device 40.

The extraction circuit 32 is arranged at the output of the receiver 30 (i.e., the second active element 31). The extraction circuit 32 extracts AC components from a signal received by the second active element 31. The amplification circuit 36 amplifies an AC signal that is extracted by the extraction circuit 32.

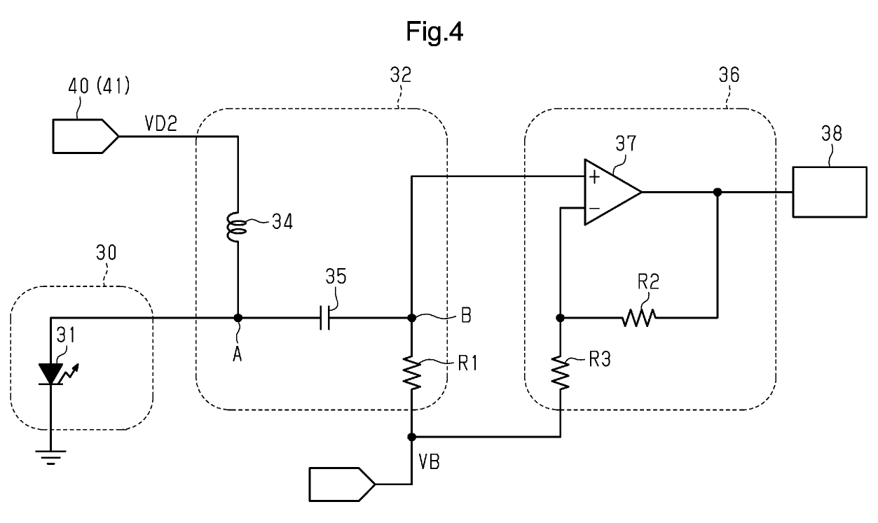

The low-pass filter circuit 38 is arranged at the output of the amplification circuit 36. The low-pass filter circuit 38 removes noise components (i.e., high-frequency components) from the signal amplified by an operational amplifier 37 of the amplification circuit 36 (refer to FIG. 4). The low-pass filter circuit 38 outputs a signal that is input to the control device 40.

The signal input to the control device 40 corresponds to data indicating a signal strength SS of the terahertz waves W received by the second active element 31. The data of the signal strength SS detected by the second active element 31 over a predetermined time interval Ta is referred to as time-series data D1. In this case, the time-series data D1 is periodically input to the control device 40.

### The Control Device

The control device 40 is electrically connected to the transmitter 20 and the receiver 30. The control device 40 is configured to control the transmitter 20 and the receiver 30. The control device 40 includes control circuitry 41. The control circuitry 41 is configured to output the first drive voltage VD1 to the transmitter 20, and output the second drive voltage VD2 to the receiver 30. The first drive voltage VD1 is applied to the transmitter 20, and the second drive voltage VD2 is applied to the receiver 30.

The first drive voltage VD1 and the second drive voltage VD2 may be generated by the control circuitry 41 or generated outside the control device 40. When the two drive voltages VD1 and VD2 are generated outside the control device 40, the control circuitry 41 may be configured to transfer the drive voltages VD1 and VD2, received from outside the control device 40, to the transmitter 20 and the receiver 30.

### Circuit Configuration

The circuit configuration of the transmitter 20, the receiver 30, the extraction circuit 32, and the amplification circuit 36 will now be described. To simplify illustration, the two active elements 21 and 31 will be described as RTDs.

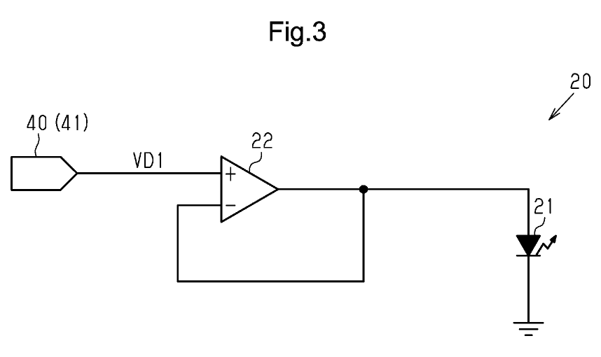

As shown in FIG. 3, the transmitter 20 includes an operational amplifier 22 in addition to the first active element 21. The non-inverting input terminal of the operational amplifier 22 is electrically connected to the control circuitry 41. The first drive voltage VD1 is input to the non-inverting input terminal. The output terminal of the operational amplifier 22 is connected to the inverting input terminal of the operational amplifier 22 and also connected to the anode of the first active element 21. The cathode of the first active element 21 is connected to ground.

An example of the circuit configuration of the receiver 30 (second active element 31), the extraction circuit 32, and the amplification circuit 36 will now be described. The circuits are not limited to the described configuration.

As shown in FIG. 4, the extraction circuit 32 includes a coil 34 and a capacitor 35. A first end of the coil 34 is connected to a first end of the capacitor 35 at node A. The anode of the second active element 31 is connected to node A. The cathode of the second active element 31 is connected to ground. A second end of the coil 34 in the extraction circuit 32 is electrically connected to the control device 40 (i.e., control circuitry 41). The second drive voltage VD2 is applied to the second end.

In this configuration, the second drive voltage VD2 is applied via the coil 34 to the second active element 31. The coil 34 allows the second drive voltage VD2 to pass while attenuating the output signal (i.e., AC components) of the second active element 31. This applies the second drive voltage VD2 to the second active element 31 while limiting the transmission of the AC components, which are received by the second active element 31, via the coil 34 to the control circuitry 41. The capacitor 35 extracts the AC components, which is a signal corresponding to the terahertz waves W, from the signal received by the second active element 31. The signal corresponding to the terahertz waves W is output from a second end of the capacitor 35. The second end of the capacitor 35 is electrically connected via node B and a resistor R1 to a terminal for applying a bias voltage VB. The resistor R1 may be omitted.

The amplification circuit 36 is arranged at the output of the extraction circuit 32 and electrically connected to the second end of the capacitor 35. The amplification circuit 36 includes, for example, the operational amplifier 37 and resistors R2 and R3. The second end of the capacitor 35 in the extraction circuit 32 is electrically connected via node B to the non-inverting input terminal of the operational amplifier 37. The inverting input terminal of the operational amplifier 37 may be electrically connected via the resistor R3 to the terminal for applying the bias voltage VB. The output terminal of the operational amplifier 37 is electrically connected to the low-pass filter circuit 38 and, via the resistor R2, to the inverting input terminal of the operational amplifier 37. In this case, the resistors R2 and R3 are connected in series between the output terminal of the operational amplifier 37 and the terminal to which the bias voltage VB is applied. The ratio of the resistors R2 and R3 determines the gain of the operational amplifier 37.

The amplification circuit 36 provides a DC offset using the bias voltage VB. An output signal of the amplification circuit 36 is input through the low-pass filter circuit 38 to the control device 40.

### The Two Active Elements and the Two Drive Voltages

The sensitivity characteristics of the two active elements 21 and 31 will now be described. The two drive voltages VD1 and VD2 will also be described. The second active element 31 and the second drive voltage VD2 will be described below in detail. The first active element 21 and the first drive voltage VD1 are similar to the second active element 31 and the second drive voltage VD2 and will not be described in order to simplify the illustration.

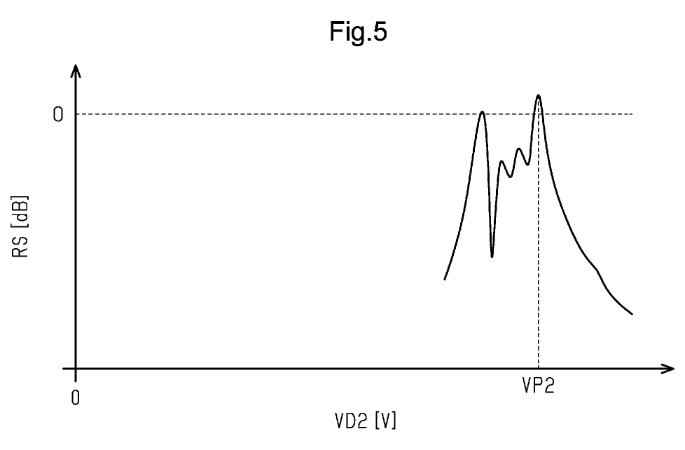

FIG. 5 is a graph showing the relationship between the second drive voltage VD2 and the receiving sensitivity RS of the terahertz waves W in the second active element 31. As shown in FIG. 5, the receiving sensitivity RS of the terahertz waves W in the second active element 31 varies sharply with respect to the second drive voltage VD2.

The second drive voltage VD2 at which the receiving sensitivity RS is maximized is set in advance as a second peak voltage VP2. The second peak voltage VP2 is a design voltage set in advance based on the specification of the second active element 31, that is, an expected voltage. In other words, the second peak voltage VP2 is set in advance as the voltage that maximizes the signal strength SS of the terahertz waves W received by the second active element 31.

The relationship between the second drive voltage VD2 and the receiving sensitivity RS varies with ambient temperature, manufacturing variations of the second active element 31, and deterioration of the second active element 31, among other factors. The second drive voltage VD2 at which the actual receiving sensitivity RS is maximized (hereinafter referred to as the second optimal voltage Vt2) may shift from the second peak voltage VP2.

The first drive voltage VD1 at which the signal strength SS of the terahertz waves W, transmitted by oscillation of the first active element 21, is maximized is set in advance as a first peak voltage VP1. The first peak voltage VP1 is a design voltage set in advance based on the specification of the first active element 21. The first peak voltage VP1 is set in advance as an expected voltage that maximizes the transmission output. The first peak voltage VP1 and the second peak voltage VP2 may be equal or unequal to each other.

The relationship between the first drive voltage VD1 and the signal strength SS (transmission output) varies with ambient temperature, manufacturing variations of the first active element 21, and deterioration of the first active element 21, among other factors. The first drive voltage VD1 at which the actual signal strength SS is maximized (hereinafter referred to as the first optimal voltage Vt1) may shift from the first peak voltage VP1.

In this respect, the control circuitry 41 of the present embodiment is configured to vary the two drive voltages VD1 and VD2 periodically and continuously.

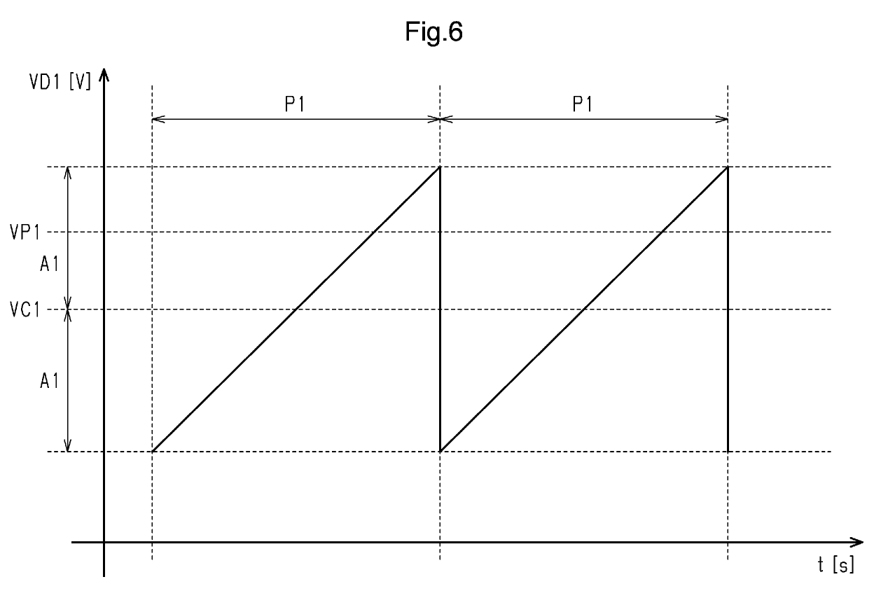

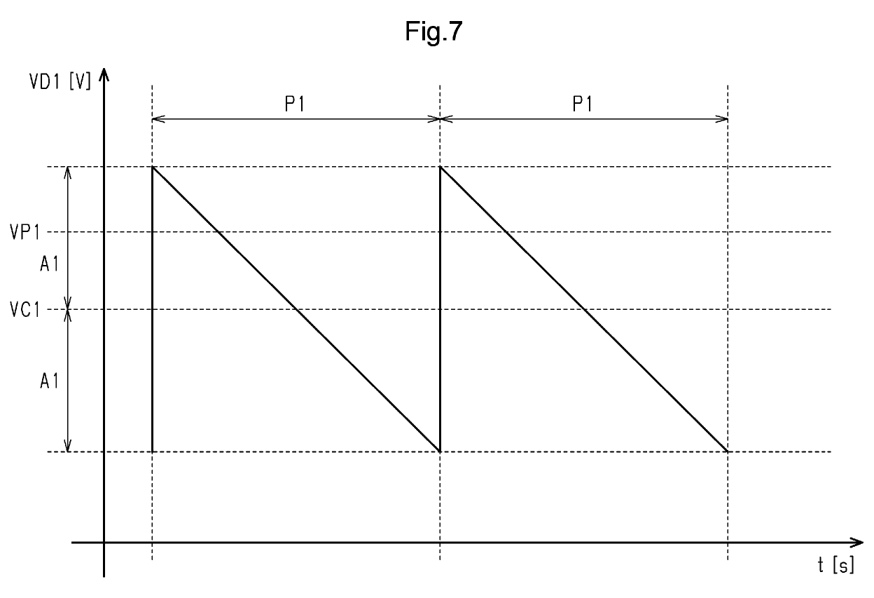

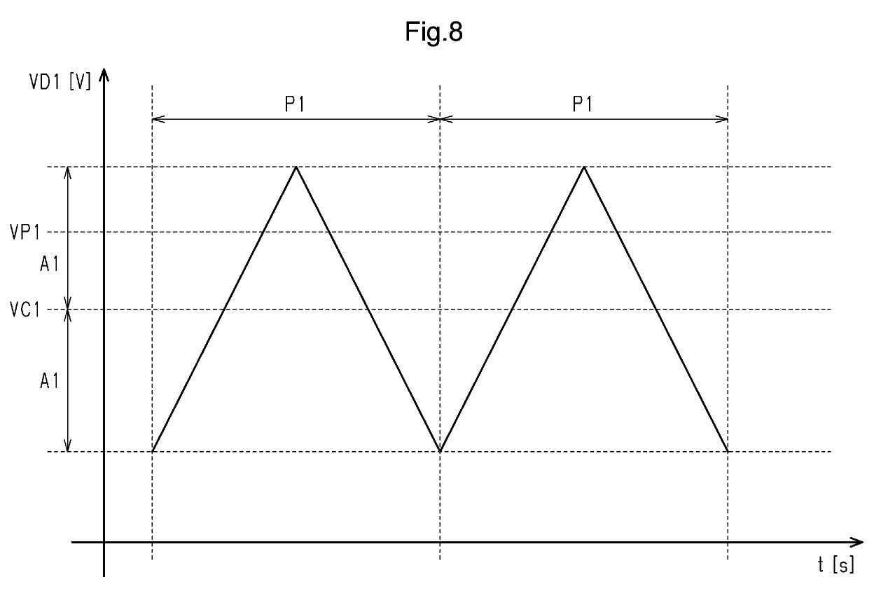

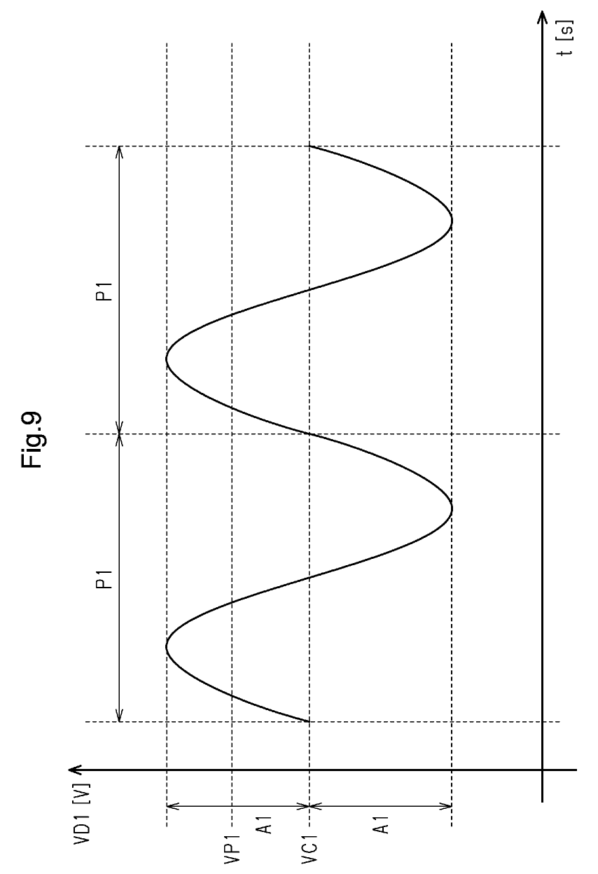

For example, as shown in FIGS. 6 to 9, the first drive voltage VD1 has a periodic waveform with a first amplitude A1 and varies continuously during each period. For example, the first drive voltage VD1 may have a ramp waveform. More specifically, as shown in FIG. 6, the first drive voltage VD1 may have, for example, a ramp-up waveform in which the voltage continuously increases during each period. As shown in FIG. 7, the first drive voltage VD1 may have a ramp-down waveform in which the voltage continuously decreases during each period. Further, as shown in FIG. 8, the first drive voltage VD1 may have a triangle waveform in which the voltage increases and decreases during each period. As shown in FIG. 9, the first drive voltage VD1 may have a sine waveform.

The first drive voltage VD1 is varied within a range including the first peak voltage VP1. For example, as shown in FIGS. 6 to 9, the first drive voltage VD1 may be a waveform having the first amplitude A1 and centered about a first center voltage VC1. The first center voltage VC1 may be set to be less than the first peak voltage VP1. In this case, the difference between the first center voltage VC1 and the first peak voltage VP1 may be less than the first amplitude A1. Therefore, the first drive voltage VD1 includes the first peak voltage VP1. Instead, for example, the first center voltage VC1 may coincide with the first peak voltage VP1. Each period of the first drive voltage VD1 is referred to as a first period P1.

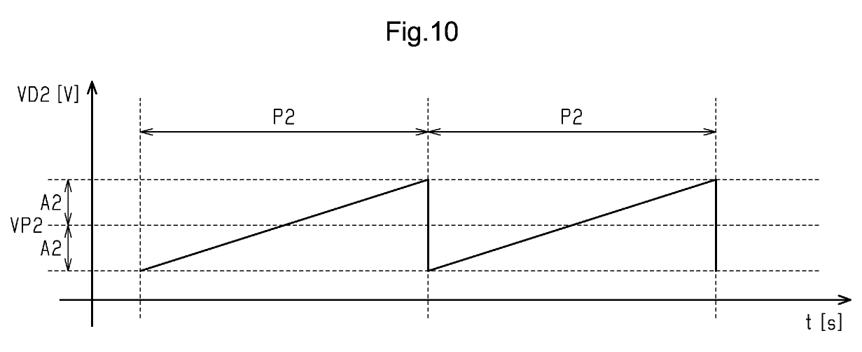

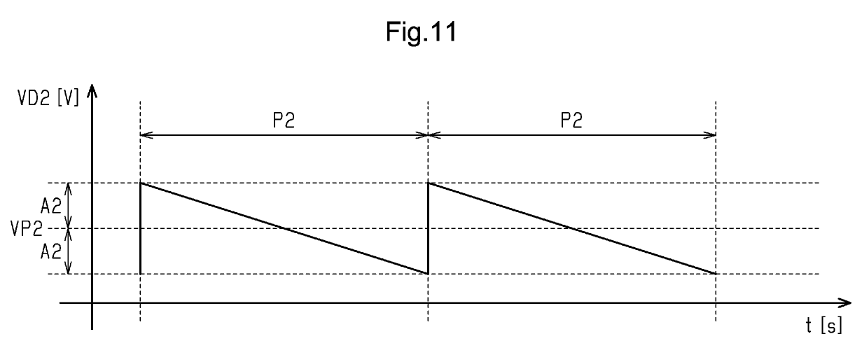

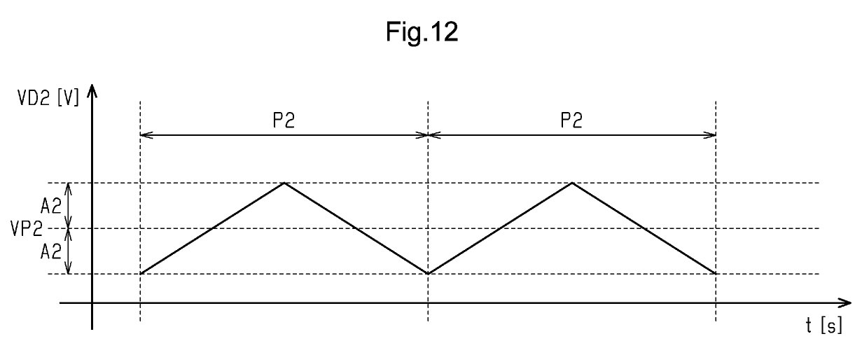

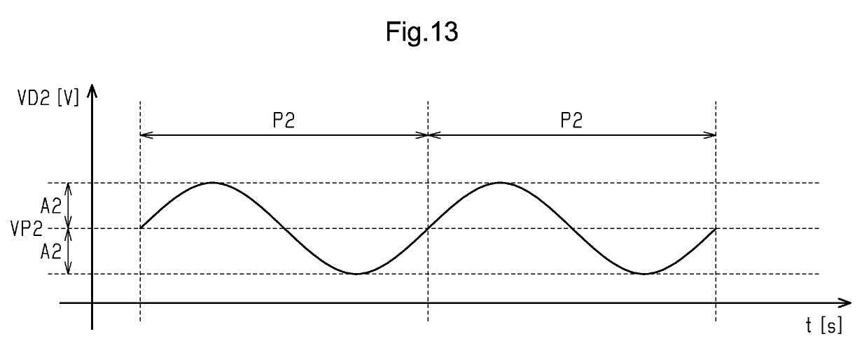

As shown in FIGS. 10 to 13, for example, the second drive voltage VD2 has a periodic waveform with a second amplitude A2 and varies continuously during each period. For example, the second drive voltage VD2 may have a ramp waveform. More specifically, as shown in FIG. 10, the second drive voltage VD2 may have, for example, a ramp-up waveform. As shown in FIG. 11, the second drive voltage VD2 may have a ramp-down waveform. As shown in FIG. 12, the second drive voltage VD2 may have a triangle waveform. As shown in FIG. 13, the second drive voltage VD2 may have a sine waveform.

The second drive voltage VD2 may be varied within a range including the second peak voltage VP2. For example, as shown in FIGS. 10 to 13, the second drive voltage VD2 may have a waveform with the second amplitude A2 and centered about the second peak voltage VP2. Each period of the second drive voltage VD2 is referred to as a second period P2.

In the present embodiment, the first center voltage VC1 may differ from the second peak voltage VP2. For example, the first center voltage VC1 may be less than the second peak voltage VP2. In this case, the difference between the first center voltage VC1 and the second peak voltage VP2 may be less than or equal to the first amplitude A1. In the present embodiment, the second peak voltage VP2 is the center voltage of the second drive voltage VD2. Therefore, the second peak voltage VP2 may be referred to as the center voltage of the second drive voltage VD2.

In a ramp waveform, the voltage varies continuously during each period and rises or falls abruptly at period boundaries. Therefore, the ramp waveform has a periodic waveform with an amplitude and varies continuously during each period. In other words, the two drive voltages VD1 and VD2 that are ramp waveforms vary periodically and continuously.

The first drive voltage VD1 and the second drive voltage VD2 may each have a frequency between 1 kHz and 10 MHz, inclusive.

For example, the second amplitude A2 may be less than the first amplitude A1. For example, the first amplitude A1 may be 50 mV to 100 mV, and the second amplitude A2 may be 10 mV to 20 mV. The second amplitude A2 may be, for example, less than or equal to 10% of the second drive voltage VD2. Further, for example, the second amplitude A2 may be less than or equal to one-tenth of the first amplitude A1.

The first amplitude A1 may be set in accordance with the characteristics of the first active element 21. For example, the first amplitude A1 may be set to be greater than a range in which the first optimal voltage Vt1 varies due to temperature changes and characteristic variations of the first active element 21. The same applies to the second amplitude A2.

The second period P2 may be less than or equal to the first period P1. For example, the second period P2 may be equal to the first period P1. In the present embodiment, the two drive voltages VD1 and VD2 are synchronized. More specifically, the two drive voltages VD1 and VD2 are aligned in phase. The two drive voltages VD1 and VD2, however, may have a phase difference.

As shown in FIG. 2, the control device 40 further includes an analog-to-digital (A/D) converter 42, analysis circuitry 44, and determination circuitry 46.

The A/D converter 42 performs A/D conversion on the time-series data D1 from the low-pass filter circuit 38 and then transmits the data to the analysis circuitry 44. As described above, the time-series data D1 is the data of the signal strength SS detected by the second active element 31 over the predetermined time interval Ta.

The analysis circuitry 44 includes, for example, one or more central processing units (CPUs) or one or more micro-processing units (MPUs) in addition to a memory. The analysis circuitry 44 is not limited to a particular configuration and may be formed by, for example, a dedicated hardware circuit.

The analysis circuitry 44 analyzes the time-series data D1 and executes received signal processing to set a determination value J used for sensing.

In the present embodiment, the time interval Ta of the time-series data D1 is greater than or equal to the first period P1 and greater than or equal to the second period P2. Therefore, the time-series data D1 includes data of the two drive voltages VD1 and VD2 that vary over each period.

### The Received Signal Processing

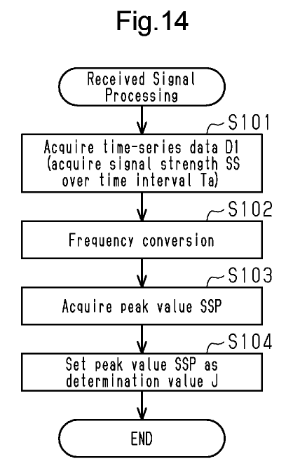

The received signal processing of the present embodiment will now be described with reference to the flowchart of FIG. 14.

In step S101, the analysis circuitry 44 acquires the time-series data D1. More specifically, the analysis circuitry 44 acquires the time-series data D1 obtained through the A/D conversion performed by the A/D converter 42.

In step S102, the analysis circuitry 44 performs frequency conversion on the time-series data D1. More specifically, the analysis circuitry 44 performs a fast Fourier transform (FFT) on the time-series data D1 to acquire frequency data D2. The frequency data D2 is the data of the signal strength SS with respect to frequency.

In step S103, the analysis circuitry 44 acquires a peak value SSP from the frequency data D2. More specifically, the analysis circuitry 44 acquires the maximum signal strength SS from the frequency data D2.

In step S104, the analysis circuitry 44 sets the peak value SSP as the determination value J.

This configuration allows the signal strength SS for a state in which the second drive voltage VD2 is the second optimal voltage Vt2 to be acquired even when the second optimal voltage Vt2 is deviated from the second peak voltage VP2.

More specifically, the time-series data D1 includes data of the signal strength SS when the second drive voltage VD2 varies. Therefore, even if the second optimal voltage Vt2 is deviated from the second peak voltage VP2, if the second optimal voltage Vt2 is included in the variation range of the second drive voltage VD2, the signal strength SS when the second drive voltage VD2 is the second optimal voltage Vt2 is reflected on the peak value SSP of the frequency data D2. Accordingly, the peak value SSP is set as the determination value J to acquire the signal strength SS stably even when the second optimal voltage Vt2 is deviated from the second peak voltage VP2. The same applies to the first drive voltage VD1.

The determination circuitry 46 includes, for example, one or more CPUs or one or more MPUs in addition to a memory. The determination circuitry 46 is not limited to a particular configuration and may be formed by, for example, a dedicated hardware circuit. The analysis circuitry 44 and the determination circuitry 46 may be formed by the same CPU, the same MPU, or by different CPUs.

The determination circuitry 46 uses the determination value J to perform various determinations. For example, the determination circuitry 46 may determine whether the detection target 50 is present or determine the state of the detection target 50 based on a ratio of the signal strength SS of the terahertz waves W transmitted from the transmitter 20 with respect to the determination value J. The state of the detection target 50 may include the material of the detection target 50 or the surface state of the detection target 50. For example, the determination circuitry 46 may use the determination value J to perform image processing that visualizes the shape of the detection target 50.

### Operation of First Embodiment

The operation of the present embodiment will now be described.

In order to limit decreases in the accuracy of detection (i.e., sensing) performed using the first active element 21 and the second active element 31, the first optimal voltage Vt1 and the second optimal voltage Vt2, at which the sensitivity is maximized, are applied to the first active element 21 and the second active element 31. The optimal voltages Vt1 and Vt2 may vary due to characteristic shifts resulting from variations in the element characteristics and temperature characteristics of the active elements 21 and 31.

In this respect, as described above, the first drive voltage VD1 and the second drive voltage VD2 are varied periodically and continuously to increase the likelihood that the first optimal voltage Vt1 is applied to the first active element 21 and the second optimal voltage Vt2 is applied to the second active element 31. This limits decreases in the imaging accuracy.

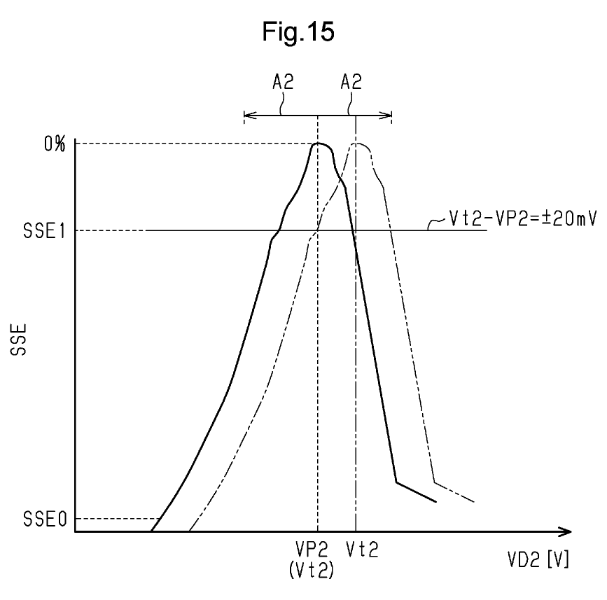

FIG. 15 is a graph showing the relationship between the second drive voltage VD2 and a signal strength error SSE. As described above, when the second optimal voltage Vt2 is set as the second peak voltage VP2, the receiving sensitivity RS is maximized and the signal strength error SSE becomes 0% when the second drive voltage VD2 reaches the second peak voltage VP2. In the DC-driving performed in the related art, when the second drive voltage VD2 is deviated from the second peak voltage VP2 (i.e., the second optimal voltage Vt2), the receiving sensitivity RS decreases and the signal strength error SSE increases.

Even if the second drive voltage VD2 is maintained at the second peak voltage VP2 in the DC-driving performed in the related art, a characteristic shift may deviate the second optimal voltage Vt2 from the second peak voltage VP2 and thereby deviate the second drive voltage VD2 from the second optimal voltage Vt2. This decreases the receiving sensitivity RS and increases the signal strength error SSE.

In this respect, the second drive voltage VD2 is varied periodically and continuously. This allows the signal strength SS to be acquired when the second drive voltage VD2 reaches the second optimal voltage Vt2. In contrast with the DC-driving performed in the related art, this limits decreases in the signal strength SS that would be caused when the second drive voltage VD2 deviates from the second optimal voltage Vt2.

In an example, under a situation in which the second optimal voltage Vt2 is deviated from the second peak voltage VP2 by 20 mV, the signal strength error SSE when DC driving is performed is a zeroth signal strength error SSE0. Further, under a situation in which the second optimal voltage Vt2 is deviated from the second peak voltage VP2 by 20 mV, the signal strength error SSE when the second drive voltage VD2 is varied periodically and continuously is a first signal strength error SSE1. In this case, the first signal strength error SSE1 is less than the zeroth signal strength error SSE0. As the deviation amount decreases between the second optimal voltage Vt2 and the second peak voltage VP2, the signal strength error SSE decreases.

### Advantages of First Embodiment

The present embodiment has the advantages described below.

(1-1) The terahertz system 10 includes the transmitter 20, which is configured to transmit the terahertz waves W, and the receiver 30, which is configured to receive the terahertz waves W. The transmitter 20 includes the first active element 21 configured to oscillate and generate the terahertz waves W when the first drive voltage VD1 is applied. The receiver 30 includes the second active element 31 configured to detect the terahertz waves W when the second drive voltage VD2 is applied. The terahertz system 10 includes the control circuitry 41 configured to output the first drive voltage VD1 and the second drive voltage VD2. The control circuitry 41 is configured to vary the first drive voltage VD1 and the second drive voltage VD2 periodically and continuously.

This configuration allows imaging to be performed using the terahertz waves W. For example, the presence or material of the detection target 50 may be determined from the ratio of the signal strength SS of the terahertz waves W transmitted from the transmitter 20 and the terahertz waves W received by the receiver 30.

In particular, the present configuration varies the two drive voltages VD1 and VD2 periodically and continuously. Therefore, even if the optimal voltages Vt1 and Vt2 vary due to characteristic shifts of the two active elements 21 and 31, the likelihood of the two drive voltages VD1 and VD2 respectively reaching the optimal voltages Vt1 and Vt2 is increased. This limits decreases in the signal strength SS, which would be caused by characteristic shifts, and allows the output characteristics of the terahertz waves W to be stable. Accordingly, decreases in the accuracy of the terahertz system 10 (in the present embodiment, decreases in the imaging accuracy), which would be caused by characteristic shifts, are limited.

The periodic and continuous variation of the first drive voltage VD1 and the second drive voltage VD2 corresponds to a method for controlling the terahertz system 10. More specifically, a method for controlling the terahertz system 10 provided with the transmitter 20 and the receiver 30 includes varying the first drive voltage VD1 and the second drive voltage VD2 periodically and continuously. This also obtains the above advantages.

(1-2) The terahertz system 10 includes the analysis circuitry 44 configured to perform frequency conversion (i.e., fast Fourier transform) on the time-series data D1 of the signal strength SS of the terahertz waves W detected by the second active element 31, and acquire the peak value SSP of the signal strength SS from the frequency data D2 obtained by the conversion.

In this configuration, the frequency data D2 is derived from the time-series data D1 by performing frequency conversion on the time-series data D1. The peak value SSP of the signal strength SS is set as the determination value J based on the frequency data D2. The peak value SSP reflects the signal strength SS when the second optimal voltage Vt2 is applied to the second active element 31. The use of the determination value J for various determinations limits decreases in the accuracy of the terahertz system 10, which would be caused by characteristic shifts. The same applies to the first active element 21 and the first optimal voltage Vt1.

(1-3) The time interval Ta of the time-series data D1 is greater than or equal to the first period P1, which is the period of the first drive voltage VD1, and greater than or equal to the second period P2, which is the period of the second drive voltage VD2.

In this configuration, the time-series data D1 includes data of the two drive voltages VD1 and VD2 that vary over each period. This increases the likelihood of the time-series data D1 including data that is taken when the drive voltages VD1 and VD2 reach the optimal voltages Vt1 and Vt2. Accordingly, decreases in the accuracy of the terahertz system 10 are limited.

(1-4) The second peak voltage VP2 is the second drive voltage VD2, which is a design voltage set to maximize the signal strength SS of the terahertz waves W received by the second active element 31. The control circuitry 41 varies the second drive voltage VD2 within a range including the second peak voltage VP2.

In this configuration, the second drive voltage VD2 is varied within a range including the second peak voltage VP2. Therefore, even when the second optimal voltage Vt2 somewhat deviates from the second peak voltage VP2, the second optimal voltage Vt2 readily falls within the varying range of the second drive voltage VD2. This allows the time-series data D1 to include the signal strength SS taken when the second optimal voltage Vt2 is applied. Accordingly, decreases in the accuracy of the terahertz system 10, which would be caused by characteristic shifts, are limited.

The same applies to the first drive voltage VD1. More specifically, the first drive voltage VD1 at which the signal strength SS of the terahertz waves W, transmitted by oscillation of the first active element 21, is maximized is set in advance as a first peak voltage VP1. The control circuitry 41 may vary the first drive voltage VD1 within a range including the first peak voltage VP1.

(1-5) The control circuitry 41 may be configured to set the second drive voltage VD2 as a periodic waveform having the second amplitude A2 and centered about the second peak voltage VP2.

In this configuration, regardless of whether the second optimal voltage Vt2 becomes lower than or higher than the second peak voltage VP2, the likelihood of the signal strength SS being included in the time-series data D1 when the second optimal voltage Vt2 is applied is increased. Accordingly, decreases in the accuracy of the terahertz system 10, which would be caused by characteristic shifts, are limited.

(1-6) The control circuitry 41 is configured to set the second drive voltage VD2 to have one of a sine waveform, a ramp waveform, and a triangle waveform, each with the second amplitude A2. This obtains the above advantages with a relatively simple waveform. A ramp waveform includes both a ramp-up waveform and a ramp-down waveform.

The same applies to the first drive voltage VD1. More specifically, the control circuitry 41 may set the first drive voltage VD1 to have one of a sine waveform, a ramp waveform, and a triangle waveform, each with the first amplitude A1.

(1-7) The first drive voltage VD1 and the second drive voltage VD2 each have a frequency between 1 kHz and 10 MHz, inclusive.

In this configuration, with respect to the terahertz waves W, which have a frequency from 0.1 THz to 10 THz, the two drive voltages VD1 and VD2 are each set to have the above frequency in order to transmit and receive the terahertz waves W while the optimal voltages Vt1 and Vt2 are applied.

(1-8) The first drive voltage VD1 is a waveform having the first amplitude A1 and varying continuously during each period. The second drive voltage VD2 is a waveform having the second amplitude A2 and varying continuously during each period. The second period P2, which is the period of the second drive voltage VD2, is less than or equal to the first period P1, which is the period of the first drive voltage VD1.

In this configuration, the second period P2 is set to be less than or equal to the first period P1. Therefore, when the first drive voltage VD1 varies in only one period, the second drive voltage VD2 will have varied over at least one period. This allows the signal strength SS taken when the second drive voltage VD2 reaches the second optimal voltage Vt2 to be acquired even when the two drive voltages VD1 and VD2 vary periodically and continuously.

(1-9) The second amplitude A2 is less than the first amplitude A1.

This configuration limits sharp changes in the sensitivity of the second active element 31 that would occur when the second amplitude A2 varies significantly. Therefore, as described with reference to FIG. 15, decreases in the accuracy of the terahertz system 10, caused by a significant decrease in the sensitivity of the second active element 31, are limited.

(1-10) The second amplitude A2 is less than or equal to 10% of the second drive voltage VD2.

As described with reference to FIG. 15, this configuration limits decreases in the accuracy of the terahertz system 10 by limiting a significant decrease in the sensitivity of the second active element 31.

(1-11) The terahertz system 10 includes the extraction circuit 32 arranged at the output of the second active element 31, the amplification circuit 36, and the low-pass filter circuit 38 arranged at the output of the amplification circuit 36. The extraction circuit 32 extracts the terahertz waves W from signals received by the second active element 31. The amplification circuit 36 amplifies the terahertz waves W extracted by the extraction circuit 32.

This configuration extracts variations from the terahertz waves W received by the second active element 31 and then amplifies the terahertz waves W. This allows the time-series data D1 to be acquired free from noise.

(1-12) The transmitter 20 and the receiver 30 are arranged on opposite sides of the detection target 50 in the first direction X. The transmitter 20 transmits the terahertz waves W in the first direction X toward the receiver 30, and the receiver 30 receives the terahertz waves W from the transmitter 20.

This configuration allows for imaging of the detection target 50 by using the terahertz waves W that pass through the detection target 50.

(1-13) The control device 40 is configured to control the transmitter 20 and the receiver 30. The transmitter 20 includes the first active element 21 configured to oscillate and generate the terahertz waves W when the first drive voltage VD1 is applied. The receiver 30 includes the second active element 31 configured to detect the terahertz waves W when the second drive voltage VD2 is applied. The control device 40 includes the control circuitry 41 configured to vary the first drive voltage VD1 and the second drive voltage VD2 periodically and continuously. This configuration obtains advantage (1-1).

The control device 40 executes control of the two drive voltages VD1 and VD2 that corresponds to a method for controlling the transmitter 20 and the receiver 30. More specifically, a method for controlling the transmitter 20 and the receiver 30 includes varying the first drive voltage VD1 and the second drive voltage VD2 periodically and continuously. This also obtains advantage (1-1).

### Second Embodiment

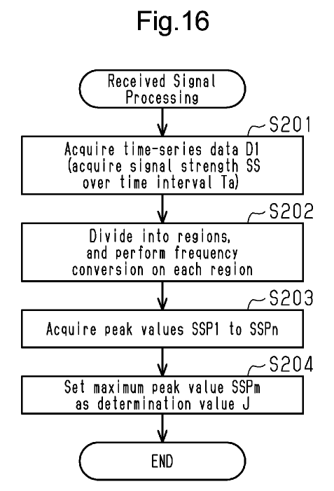

The present embodiment differs from the first embodiment in the contents of the received signal processing. The difference will now be described with reference to FIG. 16.

As shown in FIG. 16, in step S201, the analysis circuitry 44 acquires the time-series data D1. More specifically, the analysis circuitry 44 acquires the time-series data D1 obtained through the A/D conversion performed by the A/D converter 42.

In step S202, the analysis circuitry 44 divides the time-series data D1 into regions. Further, the analysis circuitry 44 performs frequency conversion on the data divided into regions to derive frequency datasets D21 to D2n. The frequency conversion is, for example, short-time Fourier transform (S-TFT). There is no limit to the number of regions. In the present embodiment, the analysis circuitry 44 that executes the conversion of step S202 corresponds to “the conversion circuitry.”

In step S203, the analysis circuitry 44 acquires peak values SSP1 to SSPn from the frequency datasets D21 to D2n. This acquires the peak values SSP1 to SSPn. In the present embodiment, the analysis circuitry 44 that executes the process of step S203 corresponds to “the acquisition circuitry.”

In step S204, the analysis circuitry 44 sets the maximum peak value SSPm, from among the peak values SSP1 to SSPn, as the determination value J. The determination circuitry 46 uses the determination value J to perform various determinations. The determinations given by the determination circuitry 46 using the determination value J are similar to the first embodiment and will not be described in detail. In the present embodiment, the analysis circuitry 44 that executes the process of step S204 corresponds to “the setting circuitry.”

### Operation and Advantages of Second Embodiment

(2-1) The terahertz system 10 includes the analysis circuitry 44 configured to analyze the time-series data D1 of the signal strength SS of the terahertz waves W detected by the second active element 31. The analysis circuitry 44 is configured to divide the time-series data D1 into regions and perform frequency conversion (step S202). The analysis circuitry 44 is configured to acquire the peak values SSP1 to SSPn of the signal strength SS from the frequency datasets D21 to D2n obtained by the conversion in each of the regions (step S203). The analysis circuitry 44 is configured to set the maximum peak value SSPm, from among the peak values SSP1 to SSPn, as the determination value J (step S204).

In this configuration, the time-series data D1 is divided into regions, and frequency conversion, more specifically, short-time Fourier transform (S-TFT), is performed on each region. This reflects the signal strength SS taken when the second drive voltage VD2 reaches the second optimal voltage Vt2 on the determination value J. Accordingly, the accuracy of the terahertz system 10 is improved. The same applies to the first drive voltage VD1 and the first optimal voltage Vt1.

More specifically, the signal strength SS in the time-series data D1 includes both an optimal region, in which the second optimal voltage Vt2 is applied to the second active element 31, and a non-optimal region, in which the second drive voltage VD2 applied to the second active element 31 differs from the second optimal voltage Vt2. In this case, as the non-optimal region becomes larger than the optimal region, the peak value SSP is less likely to reflect the signal strength SS in the optimal region. Further, the peak value SSP may not be acquired.

In this regard, in the present embodiment, the time-series data D1 is divided into regions, and frequency conversion is performed on each region to acquire the signal strength SS of each region. The peak values SSP1 to SSPn of the regions are acquired. Then, the maximum peak value SSPm, among the peak values SSP1 to SSPn, is set as the determination value J. The maximum peak value SSPm is most likely to correspond to the peak value SSP of the optimal region and is unlikely to be affected by the peak value SSP of the non-optimal region. This allows the signal strength SS to be acquired with higher accuracy than the first embodiment and increases the accuracy of the terahertz system 10.

### Modified Examples

The above embodiments may be modified as described below. The modified examples described below may be combined as long as there is no technical contradiction.

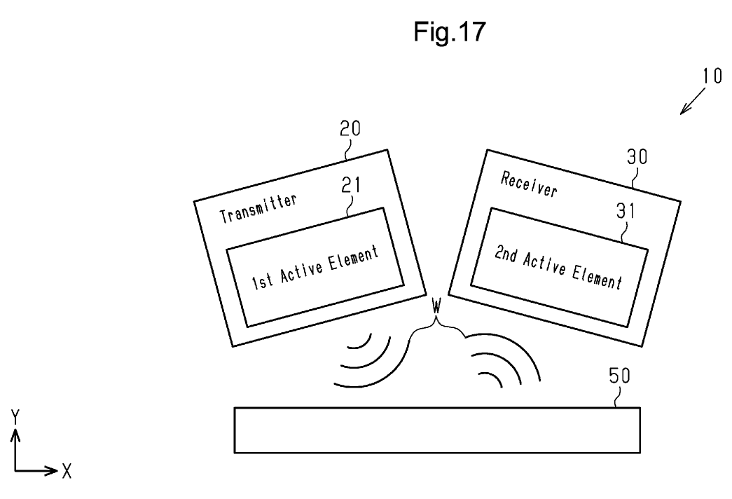

As shown in FIG. 17, the transmitter 20 may be located at any position as long as it emits the terahertz waves W toward the detection target 50, and the receiver 30 may be located at any position as long as it receives the terahertz waves W reflected by the detection target 50. For example, the transmitter 20 (i.e., the first active element 21) may be inclined relative to both the first direction X and a second direction to transmit the terahertz waves W toward the detection target 50 in a direction intersecting both the first and second directions X and Y. The receiver 30 (i.e., the second active element 31) may be inclined relative to both the first and second directions X and Y to receive the terahertz waves W reflected by the detection target 50.

The transmitter 20 (i.e., the first active element 21) may transmit the terahertz waves W while scanning in two directions orthogonal to the transmission direction of the terahertz waves W to analyze a two-dimensional region of the detection target 50.

The receiver 30 is separate from the extraction circuit 32. Instead, the receiver 30 may include the extraction circuit 32. The same applies to the amplification circuit 36 and the low-pass filter circuit 38.

At least one of the extraction circuit 32, the amplification circuit 36, and the low-pass filter circuit 38 may be omitted.

The A/D converter 42 may be separate from the control device 40. The receiver 30 may include the A/D converter 42. The determination circuitry 46 may be separate from the control device 40.

The time interval Ta of the time-series data D1 may be shorter than the first period P1 and the second period P2.

The second drive voltage VD2 may have a periodic waveform in which the second peak voltage VP2 is not the center voltage. That is, the center voltage of the second drive voltage VD2 may differ from the second peak voltage VP2.

The first drive voltage VD1 may be a waveform having the first amplitude A1 and centered about the first peak voltage VP1. That is, the first peak voltage VP1 may be equal to the first center voltage VC1.

The first center voltage VC1 and the second drive voltage VD2 may have the same center voltage or have different center voltages.

The first drive voltage VD1 and the second drive voltage VD2 may have different waveforms. For example, the first drive voltage VD1 may have a sine waveform and the second drive voltage VD2 may have a ramp waveform or vice versa.

The second drive voltage VD2 may be any periodic waveform that is continuous during each period. The same applies to the first drive voltage VD1.

The two drive voltages VD1 and VD2 may each have a frequency that is less than 1 kHz or greater than 10 MHz.

The second period P2 may be greater than the first period P1.

The first amplitude A1 may be equal to the second amplitude A2.

The second amplitude A2 may be greater than one-tenth of the second drive voltage VD2.

The transmitter 20 may include first output circuitry configured to output the first drive voltage VD1, and the receiver 30 may include second output circuitry configured to output the second drive voltage VD2. In this case, the two output circuitries are electrically connected to synchronize the two drive voltages VD1 and VD2.

Terms such as “first,” “second,” and “third” in this disclosure are used to distinguish subjects and not used for ordinal purposes.

### Clauses

Technical concepts that can be understood from each of the above embodiments and modified examples will now be described. Reference characters used in the described embodiment are added to corresponding elements in the clauses to aid understanding without any intention to impose limitations to these elements. The reference characters are provided for illustrative purposes only and are not intended to limit the elements to those denoted by the reference characters.

### Clause 1

A terahertz system (10), including:

a transmitter (20) configured to transmit terahertz waves (W) and including a first active element (21) configured to oscillate and generate the terahertz waves when a first drive voltage (VD1) is applied;

a receiver (30) configured to receive the terahertz waves and including a second active element (31) configured to detect the terahertz waves when a second drive voltage (VD2) is applied; and

control circuitry (41) configured to output the first drive voltage and the second drive voltage,

where the control circuitry is configured to vary the first drive voltage and the second drive voltage periodically and continuously.

### Clause 2

The terahertz system according to clause 1, further including analysis circuitry (44) configured to perform frequency conversion on time-series data (D1) of a signal strength (SS) of the terahertz waves detected by the second active element and acquire a peak value (SSP) of the signal strength from frequency data (D2) obtained by the conversion.

### Clause 3

The terahertz system according to clause 1, further including:

analysis circuitry (44) configured to analyze time-series data (D1) of a signal strength (SS) of the terahertz waves detected by the second active element,

where the analysis circuitry includes

conversion circuitry configured to divide the time-series data (D1) into regions and perform frequency conversion,

acquisition circuitry configured to acquire peak values (SSP1 to SSPn) from frequency datasets (D21 to D2n) obtained by the conversion in each of the regions, and

setting circuitry configured to set a maximum peak value (SSPm), from among the peak values, as a determination value (J).

### Clause 4

The terahertz system according to clause 2 or 3, where a time interval of the time-series data is greater than or equal to a first period (P1) that is a period of the first drive voltage and greater than or equal to a second period (P2) that is a period of the second drive voltage.

### Clause 5

The terahertz system according to clause 1, where the second drive voltage at which a signal strength of the terahertz waves, received by the second active element, is maximized is set in advance as a second peak voltage (VP2), and the control circuitry is configured to vary the second drive voltage within a range including the second peak voltage.

### Clause 6

The terahertz system according to clause 5, where the control circuitry is configured to set the second drive voltage having a periodic waveform with a second amplitude (A2) and centered about the second peak voltage.

### Clause 7

The terahertz system according to clause 5, where the control circuitry is configured to set the second drive voltage to have one of a sine waveform, a ramp waveform, and a triangle waveform, each with a second amplitude.

### Clause 8

The terahertz system according to clause 1, where the first drive voltage at which a signal strength of the terahertz waves, transmitted by oscillation of the first active element, is maximized is set in advance as a first peak voltage (VP1), and the control circuitry is configured to vary the first drive voltage within a range including the first peak voltage.

### Clause 9

The terahertz system according to clause 8, where the control circuitry is configured to set the first drive voltage having a periodic waveform with a first amplitude (A1) and centered about the first peak voltage.

### Clause 10

The terahertz system according to clause 8, where:

the control circuitry is configured to set the first drive voltage having a periodic waveform with a first amplitude (A1) and centered about a first center voltage (VC1); and

the first center voltage is less than the first peak voltage.

### Clause 11

The terahertz system according to any one of clauses 8 to 10, where the control circuitry is configured to set the first drive voltage to have one of a sine waveform, a ramp waveform, and a triangle waveform, each with a first amplitude.

### Clause 12

The terahertz system according to any one of clauses 1 to 11, where the first drive voltage and the second drive voltage each have a frequency between 1 kHz and 10 MHz, inclusive.

### Clause 13

The terahertz system according to any one of clauses 1 to 5, where:

the first drive voltage has a periodic waveform with a first amplitude (A1) and varies continuously during each period;

the second drive voltage has a periodic waveform with a second amplitude and varies continuously during each period; and

a second period that is a period of the second drive voltage is less than or equal to a first period that is a period of the first drive voltage.

### Clause 14

The terahertz system according to clause 13, where the second amplitude is less than the first amplitude.

### Clause 15

The terahertz system according to clause 13 or 14, wherein the second amplitude is less than or equal to 10% of the second drive voltage.

### Clause 16

The terahertz system according to any one of clauses 13 to 15, where the first drive voltage and the second drive voltage are aligned in phase.

### Clause 17

The terahertz system according to any one of clauses 1 to 16, further including:

an extraction circuit (32) arranged at an output of the second active element and configured to extract the terahertz waves from a signal received by the second active element;

an amplification circuit (36) configured to amplify the terahertz waves extracted by the extraction circuit; and

a low-pass filter circuit (38) arranged at an output of the amplification circuit.

### Clause 18

The terahertz system according to any one of clauses 1 to 17, where:

the transmitter and the receiver are arranged on opposite sides of a detection target (50) in a first direction (X);

the transmitter transmits the terahertz waves in the first direction toward the receiver; and

the receiver receives the terahertz waves transmitted from the transmitter.

### Clause 19

The terahertz system according to any one of clauses 1 to 17, where:

the transmitter is positioned to emit the terahertz waves toward a detection target; and

the receiver is positioned to receive the terahertz waves reflected by the detection target.

### Clause 20

A control device (40) for controlling a transmitter (20) including a first active element (21) configured to oscillate and generate terahertz waves (W) when a first drive voltage (VD1) is applied, and a receiver (30) including a second active element (31) configured to detect the terahertz waves when a second drive voltage (VD2) is applied, the control device (40) including:

control circuitry (41) configured to vary the first drive voltage and the second drive voltage periodically and continuously.

### Clause 21

A method for controlling a terahertz system (10) including a transmitter (20) configured to transmit terahertz waves (W) and including a first active element (21) configured to oscillate and generate the terahertz waves when a first drive voltage (VD1) is applied, and a receiver (30) configured to receive the terahertz waves and including a second active element (31) configured to detect the terahertz waves when a second drive voltage (VD2) is applied, the method including:

varying the first drive voltage and the second drive voltage periodically and continuously.

### Clause 22

A method for controlling a transmitter (20) including a first active element (21) configured to oscillate and generate terahertz waves (W) when a first drive voltage (VD1) is applied, and a receiver (30) including a second active element (31) configured to detect the terahertz waves when a second drive voltage (VD2) is applied, the method including:

varying the first drive voltage and the second drive voltage periodically and continuously.

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A terahertz system, comprising:
a transmitter configured to transmit terahertz waves and including a first active element configured to oscillate and generate the terahertz waves when a first drive voltage is applied;
a receiver configured to receive the terahertz waves and including a second active element configured to detect the terahertz waves when a second drive voltage is applied; and
control circuitry configured to output the first drive voltage and the second drive voltage,
wherein the control circuitry is configured to vary the first drive voltage and the second drive voltage periodically and continuously.

2. The terahertz system according to claim 1, further comprising analysis circuitry configured to perform frequency conversion on time-series data of a signal strength of the terahertz waves detected by the second active element and acquire a peak value of the signal strength from frequency data obtained by the conversion.

3. The terahertz system according to claim 1, further comprising:
analysis circuitry configured to analyze time-series data of a signal strength of the terahertz waves detected by the second active element,
wherein the analysis circuitry includes
conversion circuitry configured to divide the time-series data into regions and perform frequency conversion,
acquisition circuitry configured to acquire peak values from frequency datasets obtained by the conversion in each of the regions, and
setting circuitry configured to set a maximum peak value, from among the peak values, as a determination value.

4. The terahertz system according to claim 2, wherein a time interval of the time-series data is greater than or equal to a first period that is a period of the first drive voltage and greater than or equal to a second period that is a period of the second drive voltage.

5. The terahertz system according to claim 1, wherein the second drive voltage at which a signal strength of the terahertz waves, received by the second active element, is maximized is set in advance as a second peak voltage, and the control circuitry is configured to vary the second drive voltage within a range including the second peak voltage.

6. The terahertz system according to claim 5, wherein the control circuitry is configured to set the second drive voltage having a periodic waveform with a second amplitude and centered about the second peak voltage.

7. The terahertz system according to claim 5, wherein the control circuitry is configured to set the second drive voltage to have one of a sine waveform, a ramp waveform, and a triangle waveform, each with a second amplitude.

8. The terahertz system according to claim 1, wherein:
the first drive voltage at which a signal strength of the terahertz waves, transmitted by oscillation of the first active element, is maximized is set in advance as a first peak voltage; and
the control circuitry is configured to vary the first drive voltage within a range including the first peak voltage.

9. The terahertz system according to claim 8, wherein the control circuitry is configured to set the first drive voltage to have one of a sine waveform, a ramp waveform, and a triangle waveform, each with a first amplitude.

10. The terahertz system according to claim 1, wherein the first drive voltage and the second drive voltage each have a frequency between 1 kHz and 10 MHz, inclusive.

11. The terahertz system according to claim 1, wherein:
the first drive voltage has a periodic waveform with a first amplitude and varies continuously during each period;
the second drive voltage has a periodic waveform with a second amplitude and varies continuously during each period; and
a second period that is a period of the second drive voltage is less than or equal to a first period that is a period of the first drive voltage.

12. The terahertz system according to claim 11, wherein the second amplitude is less than the first amplitude.

13. The terahertz system according to claim 11, wherein the second amplitude is less than or equal to 10% of the second drive voltage.

14. The terahertz system according to claim 1, further including:
an extraction circuit arranged at an output of the second active element and configured to extract the terahertz waves from a signal received by the second active element;
an amplification circuit configured to amplify the terahertz waves extracted by the extraction circuit; and
a low-pass filter circuit arranged at an output of the amplification circuit.

15. The terahertz system according to claim 1, wherein:
the transmitter and the receiver are arranged on opposite sides of a detection target in a first direction;
the transmitter transmits the terahertz waves in the first direction toward the receiver; and
the receiver receives the terahertz waves transmitted from the transmitter.

16. The terahertz system according to claim 1, wherein:
the transmitter is positioned to emit the terahertz waves toward a detection target; and
the receiver is positioned to receive the terahertz waves reflected by the detection target.

17. A control device for controlling a transmitter including a first active element configured to oscillate and generate terahertz waves when a first drive voltage is applied, and a receiver including a second active element configured to detect the terahertz waves when a second drive voltage is applied, the control device comprising:
control circuitry configured to vary the first drive voltage and the second drive voltage periodically and continuously.
